(19) United States
(12) Patent Application Publication
(10) Pub. No.: US 2010/0032653 A1
(43) Pub. Date: Feb. 11, 2010

(54) Carbon Nanotube Electric Field Effect Transistor and Process for Producing the Same

(75) Inventors: Seiji Takeda, Hokkaido (JP); Koichi Mukasa, Hokkaido (JP); Atsushi Ishii, Hokkaido (JP); Hiroichi Ozaki, Hokkaido (JP); Makoto Sawamura, Hokkaido (JP); Hirotaka Hosoi, Hokkaido (JP); Satoshi Hattori, Hokkaido (JP); Yoshiki Yamada, Hokkaido (JP); Kazuhisa Sueoka, Hokkaido (JP)

Correspondence Address: THE NATH LAW GROUP, 112 South West Street, Alexandria, VA, 22314, US

(73) Assignee: National University Corpration Hokkaido University, Hokkaido (JP)

(21) Appl. No.: 12/225,729

(22) PCT Filed: Mar. 28, 2007
(86) PCT No.: PCT/JP2007/056580

§ 371 Date: Apr. 24, 2009

(30) Foreign Application Priority Data
Mar. 31, 2006 (JP) 2006-100958

(51) Int. Cl. H01L 29/66; H01L 21/336

(52) U.S. Cl. 257/24; 438/151; 257/E29.168; 257/E21.411; 977/938

(57) ABSTRACT

This invention provides a process for producing a carbon nanotube electric field effect transistor that can improve yield in channel preparation. Carbon nanotubes dispersed in a mixed acid composed of sulfuric acid and nitric acid are subjected to radical treatment with aqueous hydrogen peroxide to cut the carbon nanotubes and thus to provide carboxyl-introduced carbon nanotube fragments. The carbon nanotube fragments are attached, through a covalent bond and/or an electrostatic bond, to a site, where a source electrode is to be formed, and a site where a drain electrode is to be formed, in a substrate with a functional group, to be attached to a carboxyl group, introduced thereinto. The carbon nanotube fragments attached to the substrate are attached to carbon nanotubes as channels through n-n interaction to fix the carbon nanotubes as channels to the substrate.

### TECHNICAL FIELD

The present invention relates to a carbon nanotube electric field effect transistor and a method for producing the same.

### BACKGROUND ART

An electric field effect transistor (hereinafter, referred to as an “FET”) is a three- electrode transistor having a source electrode and a drain electrode, a channel connecting the both electrodes and a gate electrode, and is a transistor controlling the current between the source electrode and the drain electrode by applying voltage to the gate electrode. The FET, in which the channel is composed of carbon nanotubes (hereinafter, referred to as “CNTs”), is termed as a carbon nanotube electric field effect transistor (hereinafter, referred to as a “CNT-FET”).

A method for producing a CNT-FET is classified into a vapor growth process and a dispersion and fixation process according to a process for preparing the channel.

The “vapor growth process” is a method for producing the CNT-FET by placing a substrate on which a catalyst such as iron and the like is disposed under an atmosphere of a CNT raw material gas such as methane gas and the like, and growing CNTs which become a channel originating from the catalyst (for example, refer to Patent Document 1).

The “dispersion and fixation process” is a method for producing a CNT-FET by dispersing separately produced CNTs on a substrate and disposing CNTs which become a channel between the source electrode and the drain electrode (or between a predetermined site for forming a source electrode and a predetermined site for forming a drain electrode) on the substrate (for example, refer to Non-patent Document 1.)

On the other hand, as a technique for patterning CNTs on a substrate, there has been known a technique for fixing CNTs to which a carboxyl group is introduced by the acid treatment on a substrate to which an amino group is introduced (refer to Patent Document 2).

### Patent Document 1: Japanese Patent Publication Laid-Open No. 2004-347532

### Patent Document 2: Japanese Patent Publication Laid-Open No. 2005-40938

Non-patent Document 1: K. H. Choi, et al. “Controlled disposition of carbon nanotubes on a patterned substrate”, Surface Science, (2000), Vol. 462, p. 195-202.

### DISCLOSURE OF THE INVENTION

### Problems to be Solved by the Invention

However, the conventional method has a problem that it is difficult to produce a CNT-FET in high yield.

That is, although in order to prepare a channel by the vapor growth process, it is required to grow CNTs so as to crosslink between a source electrode and a drain electrode by controlling the growth of the CNTs, such control has a problem that it is generally difficult to be performed. In addition, although in order to prepare a channel by a conventional dispersion and fixation process, CNTs are required to be provided so as to crosslink between the electrodes, it is generally difficult to form the channel with high reproducibility, and the dispersion and fixation process has a problem with low yield.

It is an object of the present invention to provide a technique for increasing the yield of the preparation of a channel composed of CNTs and a method for producing the channel efficiently without decreasing the performance of the CNT-FET.

### Means for Solving the Problem

The present inventors have found that the yield of the production of a carbon nanotube electric field effect transistor may be increased by preparing a channel composed of carbon nanotubes using carbon nanotube fragments, and thus have completed the present invention.

That is, the first of the present invention relates to a carbon nanotube electric field effect transistor described below.

An electric field effect transistor having a source electrode and a drain electrode formed on a substrate, a channel composed of one or more carbon nanotubes connecting the source electrode and the drain electrode, and carbon nanotube fragments fixing the carbon nanotubes on the substrate, wherein the carbon nanotube fragments each have a carboxyl group or a derivative of a carboxyl group on the surface.

Further, the present invention relates to a method for producing a carbon nanotube electric field effect transistor described below.

A method for producing an electric field effect transistor having a source electrode and a drain electrode formed on a substrate and a channel composed of one or more carbon nanotubes connecting the source electrode and the drain electrode, wherein the method comprising a step of: providing an aqueous dispersion solution of carbon nanotube fragments each having a carboxyl group or a derivative of a carboxyl group on the surface to a predetermined site for forming a source electrode and a predetermined site for forming a drain electrode of the substrate; providing carbon nanotubes to the predetermined site for forming a source electrode and the predetermined site for forming a drain electrode of the substrate; and forming a source electrode at the predetermined site for forming a source electrode of the substrate and forming a drain electrode at the predetermined site for forming a drain electrode of the substrate.

A method for producing an electric field effect transistor having a source electrode and a drain electrode formed on a substrate and a channel composed of one or more carbon nanotubes connecting the source electrode and the drain electrode, wherein the method comprising a step of: providing an aqueous dispersion solution of a mixture of carbon nanotube fragments each having a carboxyl group or a derivative of a carboxyl group on the surface and carbon nanotubes to a predetermined site for forming a source electrode and a predetermined site for forming a drain electrode of the substrate; and forming a source electrode at the predetermined site for forming a source electrode of the substrate and forming a drain electrode at the predetermined site for forming a drain electrode of the substrate.

### Effect of the Invention

According to the present invention, a CNT-FET may be produced conveniently and efficiently. Accordingly, a CNT-FET may be used as a device, for example, it may be easily applied to a pH sensor, a biosensor and the like.

### BRIEF DESCRIPTION OF DRAWINGS

FIG. 1 is a view showing an example of a CNT-FET of the present invention;

FIG. 2 is a view showing an example of a substrate of a CNT-FET of the present invention;

FIG. 3 is a view showing an example of a CNT-FET of the present invention in which a channel is protected by an insulating protection film;

FIG. 4 is a view showing a condition in which CNT fragments fix a CNT which becomes a channel on a substrate;

FIG. 5 is a view showing another example of a CNT-FET of the present invention;

FIG. 6 is a view showing further another example of a CNT-FET of the present invention;

FIG. 7 is a view for illustrating a method of separately providing CNT fragments and CNTs, among the production methods of a CNT-FET of the present invention;

FIG. 8 is a view for illustrating a method of simultaneously providing CNT fragments and CNTS, among the production methods of a CNT-FET of the present invention;

FIG. 9 is a photograph showing a dispersion state of CNT fragments;

FIG. 10 is a view showing a configuration of a CNT-FET prepared in Example 1; and

FIG. 11 is a graph showing I-Vg characteristics of a CNT-FET prepared in Example 1.

### BEST MODE FOR CARRYING OUT THE INVENTION

### 1. A CNT-FET of the Present Invention

A CNT-FET of the present invention has a substrate, a source electrode and a drain electrode formed on the substrate, a channel composed of CNTs connecting the source electrode and the drain electrode, and a gate electrode. A CNT-FET of the present invention is characterized by further having carbon nanotube fragments (hereinafter, referred to as “CNT fragments”) fixing the CNTs described above on the substrate.

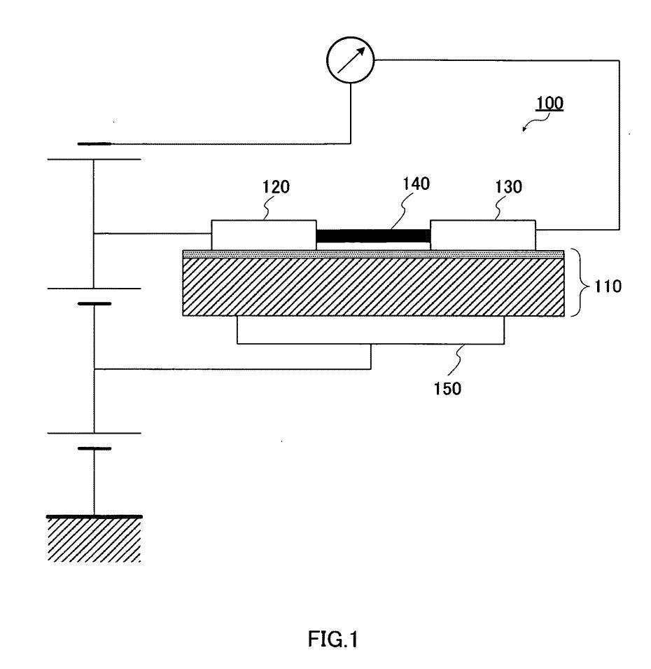

FIG. 1 is a view showing an example of the electrical connection relationship of a source electrode, a drain electrode and a gate electrode in a CNT-FET of the present invention. In FIG. 1, CNT-FET 100 has substrate 110, source electrode 120, drain electrode 130, channel 140 composed of CNTs and gate electrode 150. In this CNT-FET 100, the current between source electrode 120 and drain electrode 130 is controlled by the voltage applied to gate electrode 150.

### “Concerning a Substrate”

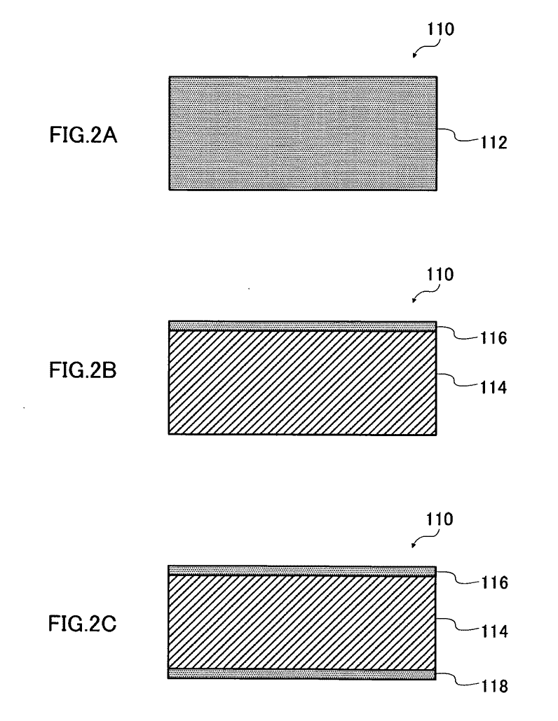

A substrate included in a CNT-FET of the present invention is preferably an insulating substrate. The insulating substrate is, for example, (1) a substrate composed of an insulator or (2) a substrate in which one surface or both surfaces of a support substrate made of a semiconductor or a metal or the like are coated with an insulating film composed of an insulator. FIG. 2 is a view showing an example of a substrate. FIG. 2A shows substrate 110 composed of insulator 112. FIG. 2B shows substrate 110 including support substrate 114 made of a semiconductor, a metal or the like and first insulating film 116 composed of an insulator. In FIG. 2B, first insulating film 116 is formed on the surface of support substrate 114 in which a source electrode and a drain electrode are formed. FIG. 2C shows substrate 110 including, in addition to support substrate 114 and first insulating film 116, further second insulating film 118 composed of an insulator.

### (1) Concerning a Substrate Composed of an Insulator

In a substrate (refer to FIG. 2A) composed of an insulator, the example of the insulator includes an inorganic compound such as silicon oxide, silicon nitride, aluminum oxide, titanium oxide and the like, an organic compound such as acrylic resin, polyimide and the like, and others. The thickness of the substrate composed of an insulator is not particularly limited and may be set accordingly.

In a method for producing a CNT-FET of the present invention, a glass substrate may be used as a substrate. Although, for example, a silicate glass (including a quartz glass) may be used, there is no limitation on the types of glass. In a production method by a conventional vapor growth process, when a channel (CNT) is prepared, it must be heated to a high temperature (approximately 900° C.) and therefore, a glass having a low glass transition temperature (for example, a glass having a glass transition temperature of approximately 400° C.) could not be used as a substrate. However, in a production method of the present invention, a glass may be used as a substrate because a substrate is not required to be heated to a high temperature.

If a glass substrate is used as a substrate, various benefits may be obtained.

(a) If a transparent glass substrate is used, there may be used an optical microscope, a fluorescent microscope, a laser microscope and the like (however, if a total internal reflection fluorescent microscope is used, a typical glass substrate is more preferable than a quartz glass substrate with respect to refractive index). That is, a device may be driven while confirming the state of a sample and a substrate with these microscopes. For example, when a CNT-FET of the present invention is applied to a biosensor, while observing with a fluorescent microscope a detection target substance such as a virus, an antigen or the like which are labeled with a fluorescent molecule, the detection target substance may be detected by measuring the change in electrical properties of the FET (for example, the change in source-drain current).

(b) If a transparent glass substrate is used, an electrode and the like may be disposed at an exact position because a film may be formed from a metal and the like on a substrate by using a marker applied on the substrate as a standard.

(c) Since a glass substrate is less expensive compared to a silicon substrate and the like, easy in processing and high in insulation, it is preferable as a substrate of the CNT-FET.

(d) Although an electrode and the like have been formed on a silicon substrate covered with an insulating film in a conventional CNT-FET, there has been occurred a tunnel current (which means that a defect is caused on an insulating film covering a silicon substrate and a current leaks in the silicon substrate). Such a phenomenon is prevented by using a glass substrate.

In addition, in a production method of a CNT-FET of the present invention, a synthetic resin substrate may be used as a substrate. A synthetic resin is further less expensive than a glass and is easy in processing, but when a synthetic resin is used as a substrate, the condition forming a film to form an electrode by deposition and the like of a metal and the like is required to be accordingly adjusted.

### (2) Concerning a Substrate Composed of a Support Substrate and an Insulating Film

In a substrate in which an insulating film is formed on a support substrate (refer to FIG. 2B and FIG. 2C), the material of the support substrate is preferably a semiconductor, a metal and the like. The example of the semiconductor includes a IV-group element such as silicon, germanium and the like; a III-V group compounds such as gallium arsenide (GaAs), indium phosphide (InP) and the like; a II-VI group compound such as zinc telluride (ZnTe) and the like; and others. The example of the metal includes aluminum, nickel and the like. In the case of a back-gate type CNT-FET (described later), the support substrate has a thickness of preferably from 0.1 to 1.0 mm and especially preferably from 0.3 to 0.5 mm, but is not particularly limited.

As the example of the material of the first insulating film formed on the first surface (the surface on which a source electrode, a drain electrode and a channel are disposed) of a support substrate, there may be included an inorganic compound such as silicon oxide, silicon nitride, aluminum oxide, titanium oxide and the like, an organic compound such as acrylic resin, polyimide and the like, and others. The thickness of the first insulating film is not particularly limited, but preferably 10 nm or more and more preferably 20 nm or more. The reason for that is that, if the first insulating film is extremely thin, a tunnel current may flow. In addition, in the case of a back-gate type CNT-FET (described later), the first insulating film has a thickness of preferably 500 nm or less and especially preferably 300 nm of less. The reason for that is that, if the first insulating film is extremely thick, a source-drain current may be difficult to be controlled by using the gate electrode.

Further, the second insulating film may be formed on the second surface (the rear surface of the first surface) of a support substrate. The material of the second insulating film is similar to that of the example of the first insulating film. As with the first insulating film, the thickness of the second insulating film is preferably 10 nm or more and especially preferably 20 nm or more, but is not particularly limited. In the case of the back-gate type CNT-FET (described later), as with the first insulating film, the second insulating film has a thickness of preferably 500 nm or less and especially preferably 300 nm or less.

The surface (the first or second surface) covered with an insulating film of a support substrate is preferably flat and smooth. That is, the interface between a support substrate and an insulating film is preferably flat and smooth. The reason for that is that, if the surface of a support substrate is flat and smooth, the reliability of an insulating film covering the surface is increased. The surface covered with an insulating film of a support substrate is not particularly limited but is preferably polished. The surface smoothness of a support substrate may be confirmed with a surface roughness measurement instrument.

### “Concerning a Source Electrode and a Drain Electrode”

On the substrate of a CNT-FET of the present invention, a source electrode and a drain electrode are disposed. The example of the material of the source electrode and the drain electrode includes a metal such as gold, platinum, chromium, titanium and the like, a compound having a conductive property such as indium tin oxide (ITO) and the like, and others. The source electrode and the drain electrode may be formed in a multilayered structure by two or more metals and the like, for example, may be formed by applying a layer of gold on a layer of titanium or chromium. The source electrode and the drain electrode is formed by forming a film by depositing and the like these metals and the like on a substrate. The film thickness of the source electrode and the drain electrode is, for example, a few dozens nm but is not particularly limited.

The interval between a source electrode and a drain electrode is not particularly limited but is typically approximately from 2 to 10 μm. The interval may be further shortened to facilitate the connection between the electrodes by a CNT. The shape of a source electrode and a drain electrode is not particularly limited and may be set arbitrarily depending on the objective. For example, when a CNT-FET of the present invention is applied to a sensor, if a test solution is added dropwise on a channel, the test solution may cover the entire source electrode and drain electrode. If the test solution covers the entire source electrode and drain electrode, a probe of a current measurement apparatus may not be directly contacted with the source electrode and drain electrode and thus the source-drain current may not be accurately measured in some cases. Consequently, the length of the source electrode and drain electrode in the channel direction may be elongated (for example, to 500 μm or longer) so that the test solution may not cover the entire source electrode and drain electrode.

### “Concerning a Channel”

In a CNT-FET of the present invention, a channel connecting a source electrode and a drain electrode is composed of CNTs. Each of the CNTs composing the channel may be either a single-layer CNT or a multi-layer CNT but is preferably a single-layer CNT. In addition, a defect may be introduced in the CNT. A “defect” means a state where a carbon five-membered ring or six-membered ring composing a CNT is opened. It is speculated that the CNT to which a defect is introduced has a structure in which the rings are barely connected, but the actual structure is not known.

In a CNT-FET of the present invention, a source electrode and a drain electrode may be connected by one CNT or plural CNTs. For example, a source electrode and a drain electrode may be connected by a bundle of CNTs, or a source electrode and a drain electrode may be connected by overlapping plural CNTs. In addition, the channel of a CNT-FET of the present invention may be contacted with a substrate, and a gap between the channel and the substrate may be formed. The state of the CNTs connecting between a source electrode and a drain electrode may be confirmed by an atomic force microscope.

A carboxyl group may be introduced on the surface of the CNTs composing a channel in order to facilitate the chemical modification. Since the electrical properties of a CNT-FET may be controlled by controlling the potential of the CNT surface, the electrical properties of a CNT-FET may be easily controlled by using CNTs for which chemical modification is easily introduced as a channel. A CNT having a carboxyl group may be obtained, for example, by the acid treatment of a CNT. In addition, the carboxyl group introduced on the surface of the CNT may be derivatized, for example, may be converted into an ester group or an amide group.

Further, CNTs composing a channel may be protected by an insulating protection film in order to prevent damage. If CNTs are coated with an insulating protection film, the entire CNT-FET may be washed with ultrasonic cleaning or with the use of a strong acid or base. In addition, since the damage of the CNTs is prevented by providing an insulating protection film, the life span of a CNT-FET may be significantly extended. The insulating protection film is not particularly limited as long as it is a film having an insulation property, for example, a film formed by an insulating adhesive, a passivation film or the like.

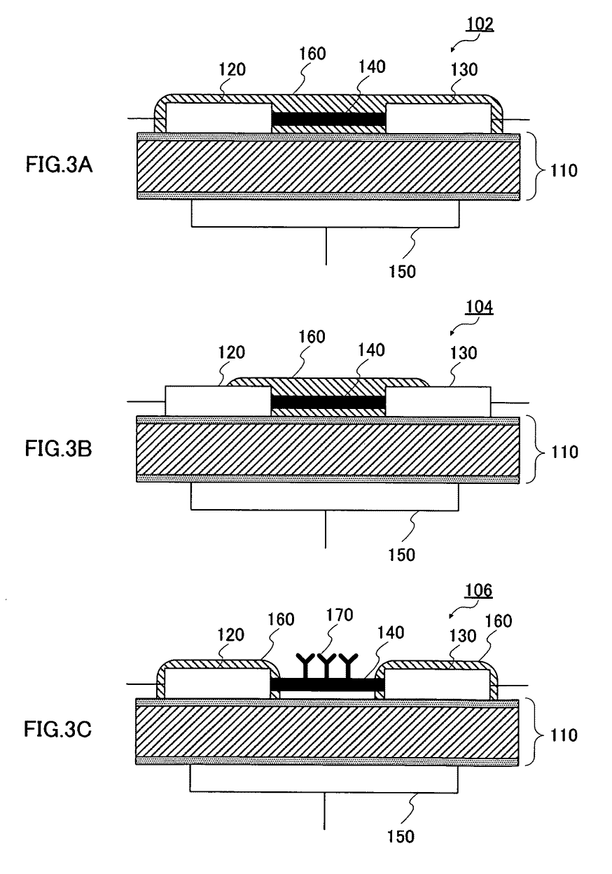

FIG. 3 is a view showing an example of a CNT-FET of the present invention in which a channel is protected by an insulating protection film. In FIG. 3, CNT-FET 102 to 106 have substrate 110, source electrode 120, drain electrode 130, channel 140 composed of CNTs, gate electrode 150 and insulating protection film 160. In FIG. 3A, the whole of source electrode 120 and drain electrode 130 and the whole of channel 140 are protected by insulating protection film 160. In FIG. 3B, part of source electrode 120 and drain electrode 130 and the whole of channel 140 are protected by insulating protection film 160. In FIG. 3C, the connection portion between source electrode 120 and channel 140 and the connection portion between drain electrode 130 and channel 140 are protected by insulating protection film 160. In the example of FIG. 3C, when CNT-FET 220 is applied to a sensor, since detected substance recognition molecule 170 such as an antibody and the like may be directly bonded to channel 140 composed of CNTs, the sensitivity of the sensor may be increased.

A channel of a CNT-FET of the present invention may be formed by an arbitrary method, but is preferably formed by a production method of the present invention described later.

### “Concerning CNT Fragments Fixing CNTs”

A CNT-FET of the present invention is characterized by containing CNT fragments fixing CNTs composing a channel on a substrate.

The “CNT fragments” mean cut pieces of CNTs and have a length of approximately 1.5 μm or less. A functional group such as a carboxyl group and the like is preferably introduced on the surface of CNT fragments. The CNT fragments having a carboxylic group may be obtained, for example, by subjecting the CNTs dispersed in acid to an oxidation treatment or a radical treatment, and the specific treatment method is described later. In addition, the carboxyl group introduced on the surface of CNT fragments may be derivatized, for example, may be converted to an ester group or an amide group.

The CNT fragments may be disposed on a substrate surface on which a channel composed of CNTs are formed, and are preferably selectively disposed at a site of the substrate in which a source electrode and a drain electrode are formed. Especially, there are preferably substantially no CNT fragment between a source electrode and a drain electrode. If CNT fragments are non-selectively disposed on a substrate (for example, are disposed between a source electrode and a drain electrode), the CNT fragments may exert an influence on the electrical properties of CNTs which become a channel. As a result, the non-selectively disposed CNT fragments may reduce the performance as a transistor of the CNT-FET. The CNT fragments may be present as a single layer or a multiple layer on the surface of a substrate.

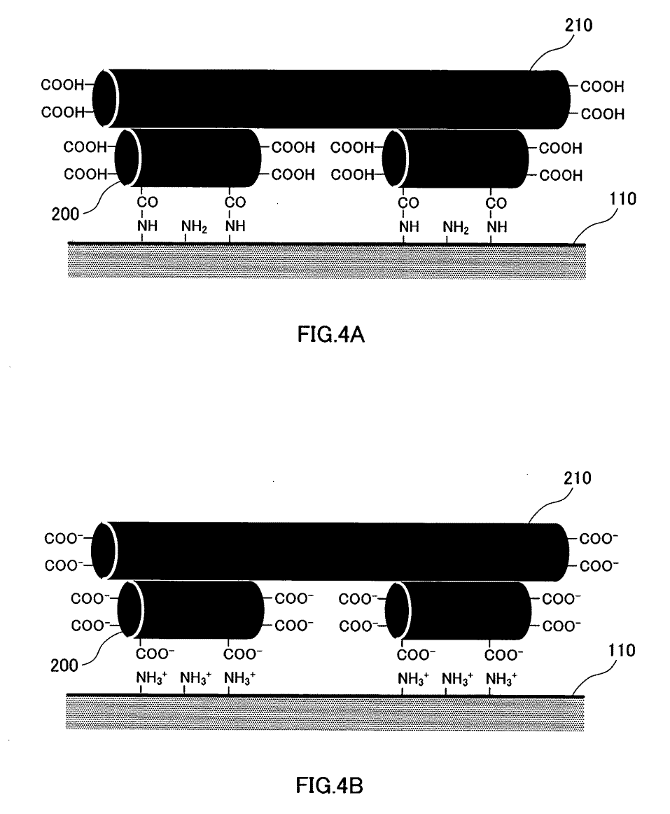

In one embodiment of the present invention, CNT fragments are covalently bonded to a substrate to which a functional group forming covalent bonding with a functional group (for example, a carboxyl group) introduced on the CNT fragment-surface is introduced. For example, as shown in FIG. 4A, CNT fragment 200 to which a carboxyl group is introduced is bonded by an amide bond, an ester bond or thioester bond to substrate 110 to which an amino group, a hydroxyl group or a thiol group is introduced.

In addition, in another embodiment of the present invention, CNT fragments are bonded by electrostatic bonding to a substrate to which a functional group forming electrostatic bonding with a functional group (for example, a carboxyl group) introduced on the CNT fragment-surface is introduced. For example, as shown in FIG. 4B, CNT fragments 200 to which a carboxyl group is introduced is electrostatically bonded to substrate 110 to which a cationic group (for example, an amino group) is introduced.

The CNT fragments bonded to a substrate fix CNTs which become a channel to the substrate through n-n interaction. That is, as shown in FIG. 4A and FIG. 4B, CNTs 210 which become a channel is fixed to substrate 110 through CNT fragments 200 bonded to the substrate by covalent bonding or electrostatic bonding.

The channel of a CNT-FET of the present invention is preferably prepared by using CNTs and CNT fragments. The preparation methods will be explained in detail later.

### “Concerning a Gate Electrode”

As mentioned above, a CNT-FET of the present invention has a gate electrode. The example of the material of the gate electrode includes a metal such as gold, platinum, chromium, titanium, brass, aluminum and the like, and others. The gate electrode is formed, for example, by forming a film by depositing and the like these metals and the like on an arbitrary position. In addition, a separately prepared electrode (for example, a thin film of gold) may be disposed on an arbitrary position to use as a gate electrode.

The position where a gate electrode is disposed is not particularly limited as long as the current (the source-drain current) between the source electrode and the drain electrode disposed on a substrate is controlled by the voltage, and may be arbitrarily determined depending on the objective. For example, a CNT-FET of the present invention may takes an embodiment of (A) a back gate type, (B) a side gate type or (C) a split-gate type depending on the position of the gate electrode.

(A) In the back gate type CNT-FET, the gate electrode is disposed on the second surface (the surface on which the source electrode, drain electrode and channel are not formed) of a substrate. The gate electrode may be disposed by contacting with the substrate surface or may be separately disposed from the substrate surface. FIG. 1 is a view showing an example of a CNT-FET of the present invention of a back gate type. In the back gate type CNT-FET 100 of FIG. 1, source electrode 120, drain electrode 130 and channel 140 composed of CNTs are disposed on the first surface of substrate 110, and gate electrode 150 is disposed on the second surface of substrate 110. In the back gate type CNT-FET 100, substrate 110 is preferably a substrate in which an insulating film is formed on a support substrate (refer to FIG. 2B or FIG. 2C).

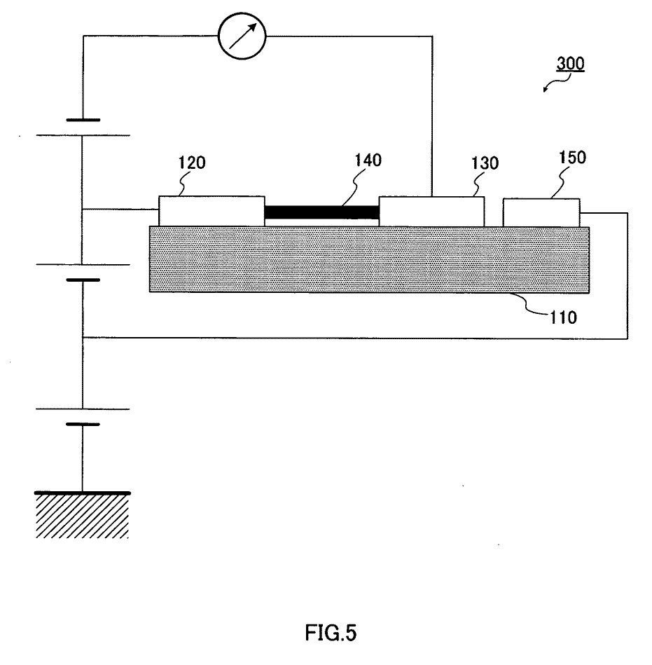

(B) In the side gate type CNT-FET, the gate electrode is disposed on the first surface (the surface on which the source electrode, drain electrode and channel are formed) of a substrate. The gate electrode may be disposed by contacting with the substrate surface or may be separately disposed from the substrate surface. When the gate electrode is separately disposed from a substrate, it may be referred to as a top gate type CNT-FET. FIG. 5 is a view showing an example of the CNT-FET of the present invention of a side gate type. In the side gate type CNT-FET 300 of FIG. 5, source electrode 120, drain electrode 130, channel 140 composed of CNTs and gate electrode 150 are disposed on the first surface of substrate 110.

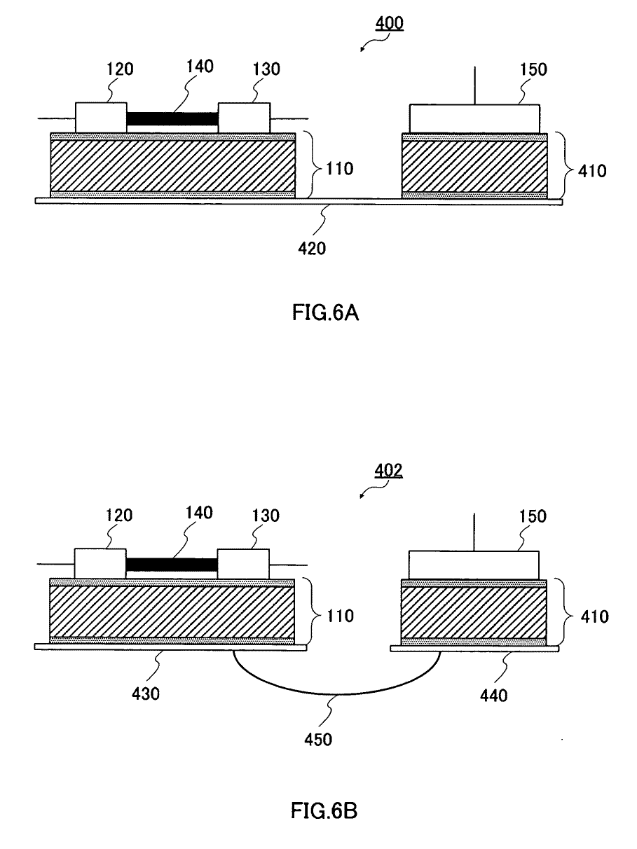

(C) In the split-gate type CNT-FET, the gate electrode is disposed on an insulating substrate, which is different from a substrate on which a source electrode and a drain electrode are disposed and is electrically connected. That being “electrically connected” means that (1) two sheets of substrates are placed on one sheet of conductive substrate, or (2) each of two sheets of substrates is placed on a separate conductive substrate connected by a conductive wire, and the like. Here the term “insulating substrate” is similar to a substrate on which the above-mentioned source electrode and drain electrode are placed. In addition, the example of the conductive substrate includes a substrate of glass or brass on which a thin film of gold is deposited, and the like. The gate electrode may be disposed by contacting with the substrate surface or may be separately disposed from the substrate surface. FIG. 6 is a view showing an example of a CNT-FET of the present invention of a split type. In FIG. 6, split-gate type CNT-FETs 400 and 402 have substrate 110, source electrode 120, drain electrode 130, channel 140 composed of CNTs, gate electrode 150, and second substrate 410 which is electrically connected with substrate 110. In split-gate type CNT-FET 400 of FIG. 6A, substrate 110 and second substrate 410 are placed on one sheet of conductive substrate 420. In split-gate type CNT-FET402 of FIG. 6B, substrate 110 and second substrate 410 are placed on separate conductive substrates 430 and 440 which are electrically connected with conductive wire 450, respectively.

A CNT-FET of the present invention preferably has a property that the source-drain current varies depending on the change in the gate voltage, when the voltage (source-drain voltage) between the source electrode and the drain electrode is held constant. For example, when the source-drain voltage is held at 35 1 V, approximately 10⁻⁹ to 10⁻⁵ A of source-drain current flows in the range of −20 to +20 V of the gate voltage, and in at least part of the range of the gate voltage, the source-drain current preferably varies depending on the change in the gate voltage.

### 2. A Method for Producing a Carbon Nanotube Electric Field Effect Transistor of the Present Invention

A method for producing a CNT-FET of the present invention is characterized by including a step of forming a channel by providing CNT fragments and CNTs to a substrate. A conventional technique may be accordingly applied for performing a step (a step of “the formation of a source electrode and a drain electrode” and “the formation of a gate electrode” and the like) except for a step of “the formation of a channel”.

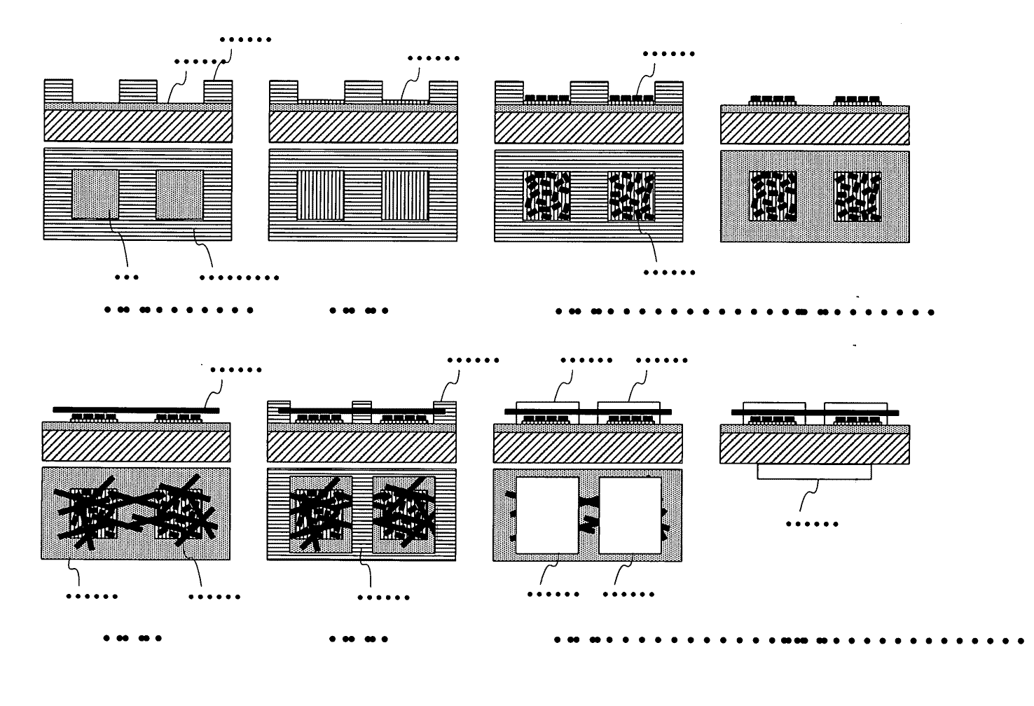

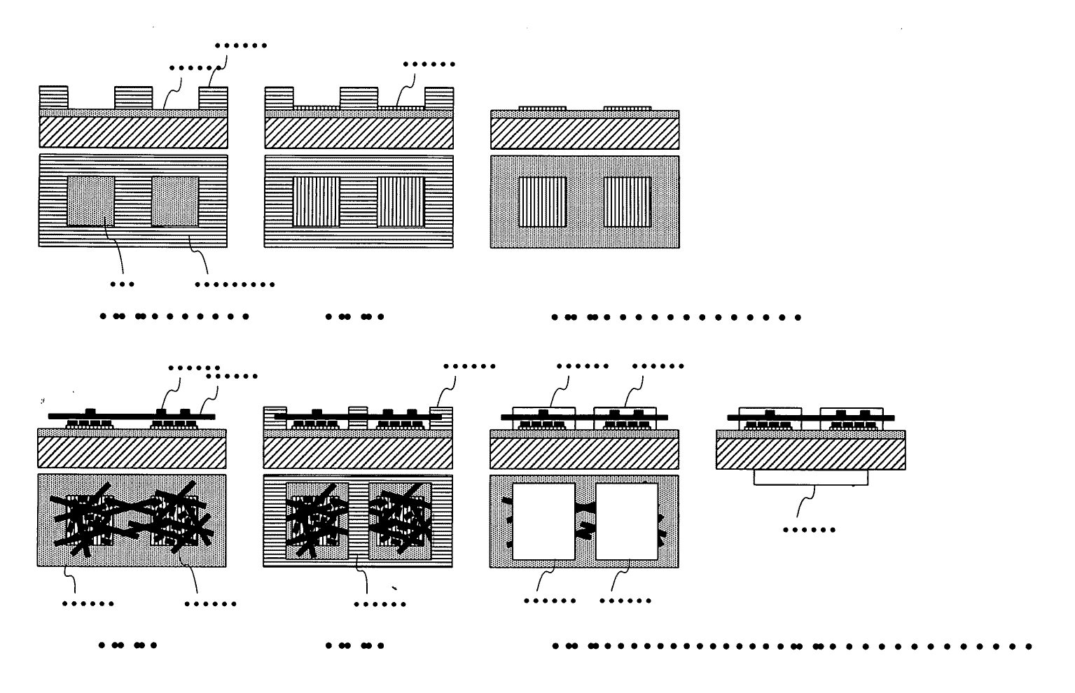

FIG. 7 and FIG. 8 are schematic views showing an example of a production method of a CNT-FET of the present invention. Hereinafter, there will be explained a production method of a CNT-FET of the present invention with reference to these drawings, the production method of a CNT-FET of the present invention is not limited by these drawings. For example, in the production method of a CNT-FET of the present invention, these drawings do not limit the order of each step, the shape and thickness of a substrate, the shape and interval of a source electrode and a drain electrode, the shape and position of a gate electrode, the length and number of the CNTs and CNT fragments, and the disposition position of CNT fragments.

### “Formation of a Channel”

In a production method of a CNT-FET of the present invention, the “formation of a channel” includes a step of “resist processing of a substrate”, “introduction of a functional group to the substrate” and “provision of CNT fragments and CNTs”.

In addition, the “formation of a channel” may be classified into two methods by the binding mode of CNT fragments to a substrate:

(A) a method of covalently binding CNT fragments to a substrate and
(B) a method of electrostatically bonding CNT fragments to a substrate.

Further, the “provision of the CNT fragments and CNTs” may be classified into two methods: (i) a method of separately providing CNT fragments and CNTs (refer to FIG. 7) and (ii) a method of simultaneously providing CNT fragments and CNTs (refer to FIG. 8).

As mentioned above, the “formation of a channel” is classified into four embodiments. Firstly, (i) and (ii) of (A) are explained, respectively, and then (i) and (ii) of (B) are explained, respectively. In addition, in Example 1 described later, the embodiment (i) of (A) is explained. In Example 2, the embodiment (i) of (B) is explained. In Example 3, the embodiment (ii) of (B) is explained.

### (A) In the Case of Bonding CNT Fragments by Covalent Bonding [Resist Processing of a Substrate]

Firstly, a substrate on which a channel is formed is prepared. The substrate is preferably an insulating substrate as mentioned above. In addition, a functional group capable of covalently bonding with a functional group (a carboxyl group or a derivative thereof) which is included in the CNT fragments is preferably introduced to a predetermined site for forming a source electrode and a drain electrode of the prepared substrate (hereinafter, also referred to as a predetermined site for electrode formation). The reason for that is that CNT fragments are made to be bonded to the predetermined site for electrode formation of the substrate.

In order to selectively introduce the functional group to the predetermined site for electrode formation of the substrate, before introducing the functional group to the substrate, it is preferable to protect a region except for the predetermined site for electrode formation of the substrate with a resist film. The type of the resist is, for example, a resist containing a resin which forms an anionic group such as a carboxyl group and the like by light irradiation, a resist containing a resin having an anionic group, and the like, but is not particularly limited. As the example of the resist containing a resin which forms a carboxyl group by light irradiation, a resist containing an alkali-soluble phenol resin is included. The resist containing an alkali-soluble phenol resin is, for example, a diazonaphthoquinone (DNQ)-based novolac resin. The resist pattern formation may be performed, for example, by developing a pattern using photolithography and protecting a region except for a predetermined site for electrode formation of a substrate with a resist film, but the resist pattern formation method is not particularly limited to this. The resist film may have a thickness of approximately 1 to 3 μm.

FIG. 7A and FIG. 8A are schematic views showing the aspect of forming resist film 500 on substrate 110 (the upper: cross-sectional views, the lower: plan views). FIG. 7A and FIG. 8A show examples of masking the region except for the predetermined site for electrode formation of the substrate with resist film 500.

### [Introduction of a Functional Group to a Substrate]

As mentioned above, it is preferable to introduce a functional group capable of covalently bonding with a functional group (a carboxyl group or a derivative thereof) which is included in CNT fragments to a predetermined site for electrode formation of a substrate. As the example of the functional group covalently bonding with a carboxyl group, an amino group, a hydroxyl group, a thiol group and the like are included.

In order to introduce an amino group to a predetermined site for electrode formation of a substrate, for example, an aminosilane film may be formed on a predetermined site for electrode formation of a substrate by adding dropwise an aminosilane on the predetermined site for electrode formation (a region which is not masked), from which the solvent was removed, and then the resultant was heated. This film is formed by condensing aminosilanes each other (for example, dehydration-condensing) by heating. The film may have a thickness of approximately 1 nm to 1 μm. The example of the aminisilane includes 3-aminopropyltriethoxysilane (APS). In addition, the introduction of a hydroxyl group to a substrate may be performed, for example, by using a hydroxysilane. Similarly, the introduction of a thiol group to a substrate may be performed, for example, by using a mercaptosilane.

FIG. 7B and FIG. 8B are schematic views (the upper: cross-sectional views, the lower: plan views) showing the aspect of forming film 510 (for example, aminosilane film) having a functional group in a region which is not masked with resist film 500 of substrate 110.

### [Provision of a CNT Fragments and CNTs]

### (i) Method of Separately Providing CNT Fragments and CNTs

In the embodiment of separately providing CNT fragments and CNTs to a substrate (refer to FIG. 7), it is preferably that firstly, an aqueous dispersion solution of CNT fragments is provided to the substrate and then CNTs are provided.

### (Provision of CNT Fragments)

An aqueous dispersion solution of CNT fragments may be a dispersion solution in which CNT fragments are uniformly dispersed in an aqueous solvent. The dispersed CNT fragments have a length of preferably approximately 1.5 μm or less. The lower limit of the length is not particularly limited but may be approximately 1 nm or more. In addition, a carboxyl group (or a derivative thereof) is preferably introduced on the surface of CNT fragments. The CNT fragments to which a carboxyl group (or a derivative thereof) is introduced may be uniformly dispersed in an aqueous solvent and may be selectively bonded to a predetermined site for electrode formation of a substrate to which a functional group covalently bonding with a carboxyl group (or a derivative thereof) is introduced.

The aqueous dispersion solution of CNT fragments may be obtained, for example, by subjecting the CNTs dispersed in acid to an oxidation treatment or a radical treatment. The oxidation treatment or the radical treatment includes a hydrogen peroxide treatment but is not particularly limited.

The length of each CNT dispersed in acid (prior to fragmentation) is not particularly limited but may be approximately 5 to 10 μm. The acid preferably contains sulfuric acid and especially preferably is a mixed acid of sulfuric acid and nitric acid. The ratio of sulfuric acid to nitric acid may be approximately sulfuric acid: nitric acid=3:1 (by volume ratio) but is not particularly limited. In addition, the amount of the mixed acid may be approximately 4 mL relative to 0.05 mg of CNTs but is not particularly limited. The CNTs dispersed in the acid are preferably subjected to an ultrasonic treatment. The CNTs dispersed in the acid, to the surface of which a carboxyl group is introduced, is increased in hydrophilicity. The CNTs dispersed in the mixed acid of sulfuric acid and nitric acid has a higher hydrophilicity than the CNTs dispersed in sulfuric acid or nitric acid and may maintain the dispersion state over a long period of time.

An aqueous dispersion solution of CNT fragments may be obtained by adding a hydrogen peroxide aqueous solution to an acid in which CNTs are dispersed. The amount of the hydrogen peroxide aqueous solution (approximately 30%) may be approximately 500 μL relative to 0.5 mg of the CNTs but is not particularly limited. After adding the hydrogen peroxide aqueous solution, the resulting aqueous dispersion solution is preferably subjected to an ultrasonic treatment. The time of the ultrasonic treatment varies depending on the state of the intended CNT fragments and is typically 3 hours or more. It is considered that a hydroxyl group is introduced to a CNT by subjecting the CNT to a hydrogen peroxide treatment and then the CNTs are cut into CNT fragments, but the process is not limited. The dispersed CNTs preferably become CNT fragments having an average length of 1.5 μm or less.

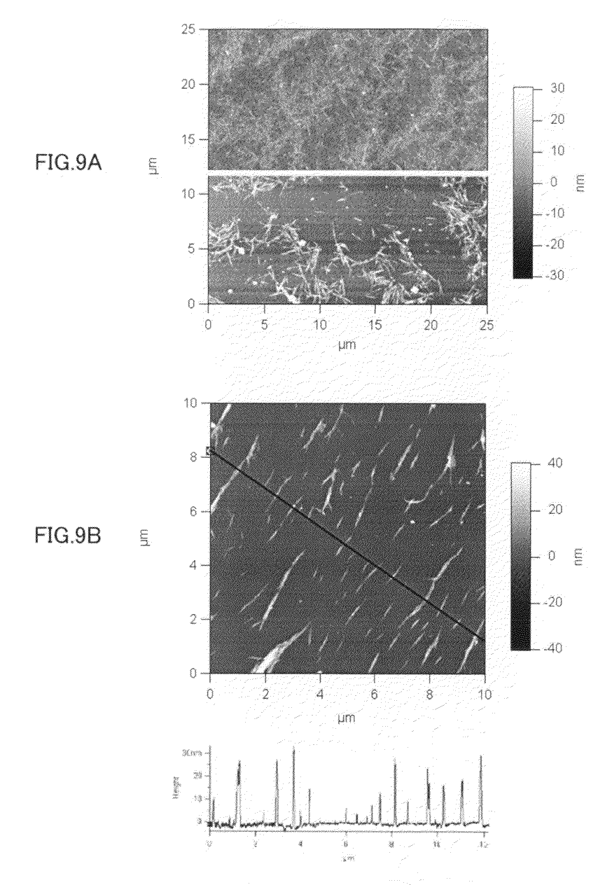

A solution is prepared by adding 0.5 mg of CNTs to a mixed acid of 3 mL of sulfuric acid and 1 mL of nitric acid. When the solution is coated on a silicon substrate and observed by an atomic force microscope, it is found out that the CNTs are present in a net-like shape (see the upper photograph of FIG. 9A). On the other hand, another solution is prepared by further adding 500 μL of an aqueous solution of hydrogen peroxide to the above solution. When the solution is coated on a silicon substrate and observed by an atomic force microscope after, it is found out that spindle-shaped CNT fragments are dispersed (see the lower photograph of FIG. 9A and the photograph of FIG. 9B). The structure of the spindle-shaped CNT fragments is not clear, but it is considered that shorter CNT fragments are agglomerated to a certain degree of length (for example, 1 μm or more) of CNT fragments. In this way, the aqueous dispersion solution of the CNT fragments obtained by subjecting to a hydrogen peroxide treatment in the mixed acid not only contains CNT fragments but also is increased in dispersibility compared to the aqueous dispersion solution obtained by dispersing CNTs only in the mixed solution.

A dispersion solution obtained by subjecting CNTs to an oxidation treatment or a radical treatment is diluted with water and the dilution is dialyzed to obtain an aqueous dispersion solution of CNT fragments having a concentration of 0.001 to 0.1 mg/mL and preferably 0.03 to 0.06 mg/mL.

If an aqueous dispersion solution of CNT fragments and a condensing agent are provided to a predetermined site for electrode formation of a substrate to which a functional group covalently binding with a carboxyl group (or a derivative thereof) is introduced, the CNT fragments are selectively bonded by covalent bonding to the predetermined site for electrode formation of the substrate. The provision of the aqueous dispersion solution of CNT fragments is performed by adding dropwise an aqueous dispersion solution containing a condensing agent on a substrate or by immersing a substrate in the aqueous dispersion solution containing the condensing agent. The pH of the mixed solution may be neutral but is not particularly limited. The temperature of the mixed solution may be room temperature but is not particularly limited.

The condensing agent is not particularly limited as long as it is a condensing agent soluble in a dispersion medium (preferably water). The example of the condensing agent includes a water-soluble carbodiimide (WSC: 1-ethyl-3-(3-dimethylaminopropyl)-carbodiimide). The use amount of the condensing agent is not particularly limited as long as the amount is enough for covalently binding a carboxyl group (or a derivative thereof) of CNT fragments to a functional group of a substrate, and the condensing agent may be used in an excessive amount for a carboxyl group (or a derivative thereof). The lower limit of the use amount of a condensing agent (that is, if a condensing agent is used in an amount more than the lower limit of the use amount, the bonding amount of CNT fragments is not increased) may be determined by bonding CNT fragments to a substrate using a condensing agent at plural different ratios to CNT fragments and then observing the bonding amount of the CNT fragments to a substrate at each ratio by an atomic force microscope. The CNT fragments are bonded to a substrate by using a condensing agent in an amount more than the lower limit of the use amount. The condensing agent may be used in an excessive amount. For example, when WSC is used as a condensing agent, the amount of the condensing agent may be set to 1 to 10 mg and preferably approximately 10 mg relative to 500 μL of an aqueous dispersion solution of 0.04 mg/mL of the CNT fragments.

After CNT fragments are bonded, the resist film is preferably removed. At this time, part of the resist film may be left without completely removing the resist film as long as the performance of a CNT-FET is not affected. If there remains a resist film containing a resin having an anionic group such as a carboxyl group in a region except for a predetermined site for electrode formation of a substrate, CNTs (to which a carboxyl group or a derivative thereof is introduced) for a channel to be subsequently provided repel against the region except for the predetermined site for electrode formation of the substrate, therefore, the non-selective bonding of CNTs to the region except for the predetermined site for electrode formation of the substrate may be reduced. The resist film containing a resin having an anionic group may be formed, for example, by exposing a DNQ-based novolac resin to natural light to hydrolyze in an aqueous solution.

FIG. 7C is a schematic view (the upper: across-sectional view, the lower: a plan view) showing an aspect of bonding CNT fragment 200 to film 510 having a functional group formed at a predetermined site for electrode formation of substrate 110. FIG. 7D is a schematic view (the upper: a cross-sectional view, the lower: a plan view) showing an aspect of removing resist film 500 after bonding CNT fragment 200.

### (Provision of CNTs)

In order to bond CNTs which become a channel to CNT fragments bonded to a predetermined site for electrode formation of a substrate, CNTs dispersed in a solution (preferably water) may be provided to the predetermined site for electrode formation of the substrate. The length of a CNT to be provided is not particularly limited but may be approximately 2 to 0 μm and preferably 5 to 10 μm. It is preferable that the CNTs dispersed in water are hydrophilized and are uniformly dispersed by an ultrasonic treatment. The hydrophilization represents, for example, an acid treatment. Specifically, CNTs may be treated with a mixed acid of sulfuric acid and nitric acid. The acid-treated CNTs are increased in dispersibility in water by introducing a carboxyl group and the like therein. Therefore, the provision of the acid-treated CNTs is preferably performed by dispersing the CNTs in an aqueous solvent. The pH of the aqueous dispersion solution may be a pKa (approximately 4 or less) of carboxylic acid or more and is preferably adjusted to 7 to 8.

The concentration of CNTs in an aqueous dispersion solution of CNTs is preferably from 0.001 to 0.1 mg/mL and more preferably from 0.03 to 0.06 mg/mL. If the concentration of CNTs is 0.1 mg/mL or higher, CNTs tend to be agglomerated, and the preparation of the aqueous dispersion solution may become difficult. On the other hand, if the concentration of CNTs is 0.001 mg/mL or lower, CNT fragments are difficult to be bonded to a substrate in some cases.

The provision of CNTs to a substrate is preferably performed by adding dropwise an aqueous dispersion solution of CNTs on a substrate or by immersing a substrate in the aqueous dispersion solution of CNTs. The aqueous dispersion solution added dropwise on the substrate or the aqueous dispersion solution in which the substrate is immersed is preferably adjusted in pH to acidic side (approximately 4 or less). If the pH of the aqueous dispersion solution is adjusted to acid, the agglomeration of CNTs is facilitated, therefore, the fixation with CNT fragments bonded to the substrate is also facilitated, and CNTs are easily bonded to the substrate. The pH may be adjusted to acid using hydrochloric acid and the like.

The provided CNTs are selectively disposed at the predetermined site for electrode formation of the substrate through n-n interaction with CNT fragments bonded to the predetermined site for electrode formation of the substrate. Part of the disposed CNTs connects between the predetermined site for forming a source electrode and the predetermined site for forming a drain electrode.

After providing CNTs and before forming an electrode, the substrate is preferably washed to remove CNTs which are not fixed. The substrate is washed, for example, by subjecting the substrate to an ultrasonic treatment in a liquid.

FIG. 7E is a schematic view (the upper: across-sectional view, the lower: a plan view) showing an aspect of bonding CNT 210 to CNT fragment 200 bonded to the predetermined site for electrode formation of substrate 110. In FIG. 7E, part of CNT 210 connects between the predetermined site for forming source electrode 120 and the predetermined site for forming drain electrode 130.

### (ii) Method for Simultaneously Providing CNT Fragments and CNTs

In the embodiment of simultaneously providing CNT fragments and CNTs to a substrate (refer to FIG. 8), it is preferable to provide an aqueous dispersion solution (hereinafter referred to as a “mixture aqueous dispersion solution”) of a mixture of CNT fragments and CNTs to the substrate.

Firstly, before providing the mixture aqueous dispersion solution to the substrate, a resist film of the substrate is removed. At this time, part of the resist film may be left without completely removing the resist film as long as the performance of a CNT-FET is not affected. If there remains a resist film containing a resin having an anionic group such as a carboxyl group in a region except for a predetermined site for electrode formation of a substrate, CNT fragments and CNTs (to which a carboxyl group or a derivative thereof is introduced) for a channel in the mixture aqueous dispersion solution to be subsequently provided repel against the region except for the predetermined site for electrode formation of the substrate, therefore, the binding rate of CNTs to the predetermined site for electrode formation of the substrate may be increased.

The mixture aqueous dispersion solution may be a dispersion solution in which CNT fragments and CNTs are uniformly dispersed in an aqueous solvent. CNT fragments have a length of preferably approximately of 1.5 μm or less. The lower limit of the length is not particularly limited but may be approximately 1 nm or more. The length of a CNT is not particularly limited but may be approximately 2 to 10 μm and preferably 5 to 10 μm. In addition, a carboxyl group (or a derivative thereof) is preferably introduced on the surface of CNT fragments. The CNT fragments, to which a carboxyl group (or a derivative thereof) is introduced, may be uniformly dispersed in an aqueous solvent and may be selectively bonded to a predetermined site for electrode formation of a substrate to which a functional group covalently bonding with a carboxyl group (or a derivative thereof) is introduced.

The mixture aqueous dispersion solution may be obtained according to the preparation method of an aqueous dispersion solution of CNT fragments and the preparation method of an aqueous dispersion solution of CNTs, as mentioned above. For example, the mixture aqueous dispersion solution may be obtained by mixing an aqueous dispersion solution of CNTs fragments and an aqueous dispersion solution of CNTs in the above-mentioned embodiment of (i) of (A). In addition, the mixture aqueous dispersion solution may also be obtained by shortening the treatment time (for example, approximately one hour) so that only part of CNTs is cut in the above-mentioned embodiment of (i) of (A). In the mixture aqueous dispersion solution obtained by the above preparation method including a hydrogen peroxide treatment, the dispersion of CNTs is stabilized compared to that of the aqueous dispersion solution obtained only by an acid treatment. The reason for that is considered that the CNT fragments generated by a hydrogen peroxide treatment are bonded to the periphery of a CNT, but the process is not limited. By the above preparation method, a mixture aqueous dispersion solution having a concentration of from 0.001 to 0.1 mg/mL and preferably from 0.03 to 0.06 mg/mL may be obtained.

If the mixture aqueous dispersion solution and a condensing agent are provided to a predetermined portion for electrode formation of a substrate to which a functional group covalently bonding with a carboxyl group (or a derivative thereof) is introduced, CNT fragments are selectively bonded by covalent bonding to the predetermined site for electrode formation. The provision of the mixture aqueous dispersion solution is performed by adding dropwise the mixture aqueous dispersion solution containing a condensing agent on a substrate or by immersing a substrate in the mixture aqueous dispersion solution. The pH of the mixed solution may be neutral but is not particularly limited. The temperature of the mixed solution may be room temperature but is not particularly limited. The condensing agent is not particularly limited as long as it is a condensing agent soluble in a dispersion medium (preferably water). For example, the same condensing agent as that in the above-mentioned embodiment of (i) of (A) may be used in the same manner.

The CNT fragments and CNTs in the mixture aqueous dispersion solution are bonded to the predetermined site for electrode formation of the substrate. At this time, it is considered that since the number of the carboxyl groups (or a derivative thereof) per unit surface area of CNTs is smaller than the number of the carboxyl groups (or a derivatives thereof) per unit surface area of CNT fragments, CNT fragments are bonded by covalent bonding to the predetermined site for electrode formation of the substrate and CNTs are selectively disposed on CNT fragments bonded to the predetermined site for electrode formation of the substrate through n-n interaction, but the process is not limited. Part of the disposed CNTs connects between the predetermined site for forming a source electrode and the predetermined site for forming a drain electrode.

After providing CNTs and before forming an electrode, the substrate is preferably washed to remove CNTs which are not fixed. The substrate is washed, for example, by subjecting the substrate to an ultrasonic treatment in a liquid.

FIG. 8C is a schematic view (the upper: cross-sectional view, the lower: plan view) showing the aspect of removing resist film 500 after film 510 having a functional group is formed on the predetermined site for electrode formation of substrate 110. FIG. 8D is a schematic view (the upper: cross-sectional view, the lower: plan view) showing the aspect of bonding CNT fragment 200 and CNT 210 to film 510 having a functional group formed at the predetermined site for electrode formation of substrate 110. In FIG. 8D, Part of CNT 210 connects between the predetermined site for forming source electrode 120 and the predetermined site for forming drain electrode 130.

### (B) In the Case of Bonding CNT Fragments by Electrostatic Bonding [Resist Treatment of Substrate]

Firstly, a substrate in which a channel is formed is prepared. The substrate preferably is an insulating substrate, as mentioned above. In addition, a functional group capable of electrostatically bonding with a carboxyl group (or a derivative thereof) is preferably introduced to a predetermined site for electrode formation of the prepared substrate. The reason for that is because CNT fragments are bonded to the predetermined site for electrode formation of the substrate.

In order to selectively introduce the functional group to the predetermined site for electrode formation of the substrate, before introducing the functional group to the substrate, it is preferable to protect a region except for the predetermined site for electrode formation of the substrate with a resist film (refer to FIG. 7A and FIG. 8A). The type of the resist is, for example, a resist containing a resin which forms an anionic group such as a carboxyl group and the like by light irradiation, a resist containing a resin having an anionic group, and the like, but is not particularly limited. As the example of the resist containing a resin which forms a carboxyl group by light irradiation, a resist containing an alkali-soluble phenol resin is included. The resist containing an alkali-soluble phenol resin is, for example, a diazonaphthoquinone (DNQ)-based novolac resin. The resist pattern formation may be performed, for example, by developing a pattern using photolithography and protecting a region except for a predetermined site for electrode formation of a substrate with a resist film, but the resist pattern formation method is not particularly limited to this. The resist film may have a thickness of approximately 1 to 3 μm.

### [Introduction of Functional Group to Substrate]

As mentioned above, a functional group capable of electrostatically bonding with a carboxyl group (or a derivative thereof) is preferably introduced to a predetermined site for electrode formation of a substrate. The functional group electrostatically bonding with a carboxyl group is not particularly limited as long as it is a cationic group. The example of the cationic group includes an amino group.

In order to introduce an amino group to a predetermined site for electrode formation, for example, as mentioned above, a film with aminosialne such as APS and the like may be formed at the predetermined site for electrode formation (refer to FIG. 7B and FIG. 8B). The film may have a thickness of approximately 1 nm to 1 μm.

### [Provision of CNT Fragments and CNTs]

### (i) Method for Separately Providing CNT Fragments and CNTs

In the embodiment of separately providing CNT fragments and CNTs to a substrate (refer to FIG. 7), it is preferable that firstly, an aqueous dispersion solution of CNT fragments is provided to the substrate and then CNTs are provided.

### (Provision of CNT Fragments)

The aqueous dispersion solution of CNT fragments may be prepared in the same manner as in the above-mentioned embodiment of (i) of (A). For example, the aqueous dispersion solution may be prepared by subjecting the CNTs dispersed in a mixed acid of sulfuric acid and nitric acid to a hydrogen peroxide treatment. An anionic carboxyl group is introduced to the CNT fragments thus obtained. The CNT fragments to which a carboxyl group is introduced may be uniformly dispersed in an aqueous solvent and may be selectively bonded to a predetermined site for electrode formation of a substrate to which a functional group electrostatically bonding with a carboxyl group is introduced.

If the aqueous dispersion solution of CNT fragments is provided to a predetermined site for electrode formation of a substrate to which a functional group electrostatically bonding with a carboxyl group (or a derivative thereof) is introduced, CNT fragments are selectively bonded by electrostatic bonding to the predetermined site for electrode formation of the substrate (refer to FIG. 7C). At this time, a condensing agent is not required to be used. The provision of the aqueous dispersion solution of CNT fragments is performed by adding dropwise the aqueous dispersion solution of CNT fragments on a substrate or by immersing a substrate in the aqueous dispersion solution of CNT fragments. The pH of the aqueous dispersion solution of CNT fragments may be neutral but is not particularly limited. The temperature of the aqueous dispersion solution of CNT fragments may be room temperature but is not particularly limited. If a resist film containing a resin having an anionic group such as a carboxyl group is used at the stage of fixing CNT fragments, CNT fragments repel against the resist film, therefore, the non-selective bonding of CNT fragments to a region except for the predetermined site for electrode formation of the substrate may be reduced.

After CNT fragments are bonded, the resist film is preferably removed (refer to FIG. 7D). At this time, part of the resist film may be left without completely removing the resist film as long as the performance of a CNT-FET is not affected. If there remains a resist film containing a resin having an anionic group such as a carboxyl group in a region except for a predetermined site for electrode formation of a substrate, CNTs (to which a carboxyl group or a derivative thereof is introduced) for a channel to be subsequently provided repel against the region except for the predetermined site for electrode formation of the substrate, therefore, the non-selective bonding of CNTs to the region except for the predetermined site for electrode formation of the substrate may be reduced. The resist film containing a resin having an anionic group may be formed, for example, by exposing a DNQ-based novolac resin to natural light to hydrolyze in an aqueous solution.

### (Provision of CNTs)

In order to bond CNTs which become a channel to CNT fragments bonded to a predetermined site for electrode formation of a substrate, CNTs dispersed in a solution may be provided to the predetermined site for electrode formation of the substrate. The provision of CNTs to the substrate is preferably performed by adding dropwise an aqueous dispersion solution of CNTs on the substrate or by immersing the substrate in the aqueous dispersion solution of CNTS. In the same manner as in the above-mentioned embodiment of (i) of (A), the aqueous dispersion solution added dropwise on the substrate or the aqueous dispersion solution in which the substrate is immersed is preferably adjusted in pH to acidic side (approximately 4 or less). The aqueous dispersion solution of CNTs may be prepared in the same manner as in the above-mentioned embodiment of (i) of (A). For example, the CNTs treated with a mixed acid of sulfuric acid and nitric acid may be dispersed in an aqueous solvent.

The provided CNTs are selectively disposed at the predetermined site for electrode formation of the substrate through n-n interaction with CNT fragments bonded to the predetermined site for electrode formation of the substrate. Part of the disposed CNTs connects between the predetermined site for forming a source electrode and the predetermined site for forming a drain electrode (refer to FIG. 7E).

After providing CNTs and before forming an electrode, the substrate is preferably washed to remove CNTs which are not fixed. The substrate is washed, for example, by subjecting the substrate to an ultrasonic treatment in a liquid.

### (ii) Method for Simultaneously Providing CNT Fragments and CNTs

In the embodiment of simultaneously providing CNT fragments and CNTs to a substrate, it is preferable to provide an aqueous dispersion solution of a mixture of CNT fragments and CNTs (a mixture aqueous dispersion solution) to the substrate.

Firstly, before providing the mixture aqueous dispersion solution to the substrate, a resist film of the substrate is removed (refer to FIG. 8C). At this time, part of the resist film may be left without completely removing the resist film as long as the performance of a CNT-FET is not affected. If there remains a resist film containing a resin having an anionic group such as a carboxyl group in a region except for a predetermined site for electrode formation of a substrate, CNT fragments and CNTs (to which a carboxyl group or a derivative thereof is introduced) for a channel in the mixture aqueous dispersion solution to be subsequently provided repel against the region except for the predetermined site for electrode formation of the substrate, therefore, the non-selective bonding of the CNT fragments and CNTs to the region except for the predetermined site for electrode formation of the substrate may be reduced.

The mixture aqueous dispersion solution may be prepared in the same manner as in the above-mentioned embodiment of (ii) of (A). For example, the mixture aqueous dispersion solution is obtained by mixing the aqueous dispersion solution of CNT fragments and the aqueous dispersion solution of CNTs in the above-mentioned embodiment of (i) of (A). In addition, the mixture aqueous dispersion solution is also obtained by shortening the treatment time (for example, approximately one hour) in the above-mentioned embodiment of (i) of (A) so that only part of CNTs is cut. An anionic carboxyl group is introduced in the CNT fragments and CNTs thus obtained. The CNT fragments to which a carboxyl group (or a derivative thereof) is introduced may be uniformly dispersed in an aqueous solvent and may be selectively bonded to a predetermined site for electrode formation of a substrate to which a functional group electrostatically bonding with a carboxyl group (or a derivative thereof) is introduced.

The provision of the mixture aqueous dispersion solution is performed by adding dropwise the mixture aqueous dispersion solution on a substrate or by immersing a substrate in the mixture aqueous dispersion solution. At this time, a condensing agent is not required to be used. The pH of the mixed solution may be neutral but is not particularly limited. The temperature of the mixed solution may be room temperature but is not particularly limited. The CNT fragments and CNTs in the mixture aqueous dispersion solution are bonded to the predetermined site for electrode formation of the substrate. At this time, it is considered that since the number of the carboxyl groups (or a derivatives thereof) per unit surface area is different between CNTs and CNT fragments, CNT fragments are bonded by electrostatically bonding to the predetermined site for electrode formation of the substrate, and CNTs are selectively disposed on the CNT fragments bonded to the predetermined site for electrode formation of the substrate through n-n interaction, but the process is not limited (refer to FIG. 8D). Part of the disposed CNTs connects between the predetermined site for forming a source electrode and the predetermined site for forming a drain electrode.

After providing CNTs and before forming an electrode, the substrate is preferably washed to remove CNTs which are not fixed. The substrate is washed, for example, by subjecting the substrate to an ultrasonic treatment in a liquid.

### “Formation of Source Electrode and Drain Electrode”

After fixing CNTs on the substrate, a source electrode and a drain electrode are formed. The means for forming a source electrode and a drain electrode at each predetermined sites for formation is not particularly limited. For example, the electrodes may be formed by masking a region except for a predetermined site for electrode formation of a substrate on which CNTs are fixed with a resist film, forming a film by depositing and the like a metal such as gold, platinum, chromium and the like, a light-permeable semiconductor, ITO and the like, and removing the resist film, by using a lithography method. In addition, an electrode with a double layer structure may be formed by forming a film by the deposition and the like of chromium, and the like, and further forming a film by the deposition and the like of gold. FIG. 7F and FIG. 8E are schematic views (the upper: cross sectional views, the lower: plan views) showing an aspect of forming resist film 500 in a region except for the predetermined site for electrode formation of substrate 110, in order to form a source electrode and a drain electrode. FIG. 7G and FIG. 8F are schematic views (the upper: cross sectional views, the lower: plan views) showing an aspect of forming source electrode 120 and drain electrode 130 by forming a film by the deposition and the like of a metal and the like and removing resist film 500.

### “Formation of Gate Electrode”

The means for forming a gate electrode is not particularly limited. For example, in the same manner as in the source electrode and the drain electrode, the gate electrode may be formed by masking a region except for a predetermined site for forming a gate electrode with a resist film, and by forming a film by the deposition and the like of a metal and the like and removing a resist film, by using a lithography method. In addition, when a separately prepared electrode is used as a gate electrode, the electrode may be disposed at a desired position. FIG. 7H and FIG. 8g are schematic views (cross-sectional views) showing an aspect of forming gate electrode 150 on the second surface (the surface on which source electrode 120 and drain electrode 130 are not formed) of substrate 110.

In a method for producing a CNT-FET of the present invention, a source electrode and a drain electrode may be connected with a high probability (approximately 100%) (that is, a channel may be prepared). Therefore, in a method for producing a CNT-FET of the present invention, the yield of the production of a CNT-FET may be increased. In addition, in a method for producing a CNT-FET of the present invention, a substrate material (for example, glass) having low heat resistance may be adopted because the substrate is not required to be heated to a high temperature.

Further, in the explanation, it is designed to modify a predetermined site for forming a source electrode and a drain electrode with a functional group. However, in a method for producing a CNT-FET of the present invention, it may be designed to modify a source electrode and a drain electrode with a functional group. In this case, CNTs may be provided to a source electrode and a drain electrode by preparing a substrate on which a source electrode and a drain electrode are formed, modifying the source electrode and the drain electrode with a functional group reacting with a carboxyl group (or a derivative thereof), and providing CNT fragments to the source electrode and the drain electrode which are modified with a functional group.

In order to introduce a functional group on the surface of an electrode (for example, a gold electrode), the electrode surface may be treated with a compound (for example, aminoalkylthiols) having a functional group (for example, a thiol group) specifically reacting with the material of the electrode. Aminoalkylthiols include 11-amino-1-undecanthiol.

After providing CNTs (further preferably after washing), an electrode is preferably formed by further depositing a metal on the electrode which has been already disposed on a substrate. An adequate source-drain current (for example, approximately 0.1 to 1.0 μA) can flow stably by further depositing a metal after providing CNTs. A device in which approximately 0.1 to 1.0 μA of current flows is not likely to be damaged by several times of washing with water and the like.

### 3. Uses of CNT-FET of the Present Invention

A CNT-FET of the present invention may be applied to arbitrary uses and may be used, for example, for a pH sensor, a biosensor and the like. A CNT-FET of the present invention may modify the surface of CNTs and fix biomolecules to CNTs more efficiently than a CNT-FET prepared by a conventional production method because CNTs which become a channel have a large number of carboxyl groups (or derivatives thereof). When a CNT-FET is used as a sensor, the modification of the CNT surface and the fixation of biomolecules on the surface of CNTs are important in increasing the sensitivity of a sensor. Therefore, a CNT-FET of the present invention may be applied as a sensor with a high sensitivity.

When a CNT-FET of the present invention is used as a biosensor, a detected substance recognition molecule is preferably bonded to a CNT-FET of the present invention. The example of the detected substance includes a microorganism such as a virus, bacterium and the like, a chemical substance such as a residual agricultural chemical and the like, a carbohydrate, nucleic acid, amino acid, fat and the like. On the other hand, the example of the detected substance recognition molecule includes an antibody, an antigen, an enzyme, a receptor, an nucleic acid, an aptamer, a cell, a microorganism and the like. For example, when the detected substance is an antigen, the detected substance recognition molecule is an antibody or an aptamer, and when the detected substance is an antibody, the detected substance recognition molecule is an antigen. The detected substance recognition molecule is preferably bonded to a CNT-FET of the present invention so that it is reacted with a detected substance to change a source-drain current. For example, the detected substance recognition molecule may be bonded to a channel composed of CNTs, a gate electrode or a substrate, an insulating protection film protecting thereof, or the like.

A biosensor using a CNT-FET of the present invention is operated with an alternating current using a resonance circuit and may detect a detected substance from the change in a source-drain current or a source-drain voltage caused by the bonding of a detected substance to a detected substance recognition molecule. The change in the source-drain current or source-drain voltage may be confirmed, for example, by the I-V characteristic curve or I-Vg characteristic curve. The I-V characteristic curve is a curve representing the relationship between a source-drain current and a source-drain voltage when a gate voltage is held constant, and the I-Vg characteristic curve is a curve representing the relationship between a gate voltage and a source-drain current when a source-drain voltage is held constant.

Further, as mentioned above, in a production method of a CNT-FET of the present invention, a glass substrate may be used as a substrate. A CNT-FET of the present invention using a transparent glass substrate may be applied not only to a product such as a memory, an electric circuit, a chemical sensor and the like but also to studies at a molecular level relating to a biomolecular reaction or an intermolecular interaction. For example, by combination with a total internal reflection fluorescence microscope (TIRF), a CNT-FET of the present invention using a transparent glass substrate may simultaneously obtain visual and electric information on a biomolecular reaction such as an intermolecular interaction of proteins, a DNA hybridization, an antigen-antibody reaction, and the like.

### EXAMPLE 1

Example 1 shows an example of preparing a CNT-FET by covalently bonding CNT fragments on a substrate.

### 1. Pretreatment of Substrate

The substrate surface except for a predetermined site for forming a source electrode and a drain electrode was protected with a resist film (OFPR800 (a resist containing an alkali-soluble phenol resin), manufactured by Tokyo Ohka Kogyo Co., Ltd.) by developing a pattern by photolithography on one surface of 1 cm² of a silicon substrate (silicon thickness: 500 μm), both surfaces of which are covered with a silicon oxide film (film thickness: 0.135 μm) (refer to FIG. 7A). The thickness of the resist film was adjusted to 1 μm. 100 μL of a 1% aqueous solution of APS (Manufactured by Sigma-Aldrich Corporation) was added dropwise on the substrate on which the resist film was formed, and the resultant was reacted at 45° C. for 15 minutes. The solvents were removed by spraying a nitrogen gas, and then the substrate was heated at 115° C. for 30 minutes to form a film with APS (refer to FIG. 7B). The APS film had a thickness of 5 nm.

### 2. Preparation of Aqueous Dispersion Solution of CNT Fragments

0.5 mg of single-layer CNTs (manufactured by Carbon Nanotrchnologies, Inc.) was suspended in a mixed acid of 3 mL of sulfuric acid and 1 mL of nitric acid, and the resultant was subjected to an ultrasonic treatment for 5 minutes. To the treated solution, an aqueous solution of hydrogen peroxide (500 μL) was added dropwise, and then the ultrasonic treatment was further performed for 4 hours. To the treated solution, water was added to make the resulting solution 8 mL, and dialyzation against 3 L of water was performed three times (molecular fractionation: 10000). To the dialyzed product, water was added to make the resulting solution 10 mL and the resulting solution was used as an aqueous dispersion solution of CNT fragments. The concentration of CNT fragments was 0.05 mg/mL.

### 3. Fixation of CNT Fragments

A mixture solution was prepared by mixing 100 μL of the aqueous dispersion solution of CNT fragments, 100 μL of a buffer solution (100 mM of NaHCO₃, pH: 8.26) and approximately 2.5 mg of a condensing agent (1-ethyl-3-(3-dimethylaminopropyl)carbodiimide). The mixture solution was added dropwise on the pretreated substrate at 40° C. over 15 minutes to bond CNT fragments to the predertermined site for electrode formation of the substrate (refer to FIG. 7C). The operations were repeated twice. The resulting substrate was subjected to an ultrasonic treatment for approximately 30 seconds in dimethylformamide (N,N-dimethylformamide, manufactured by Kanto Chemical Co., Inc.) to remove the resist film, and the resultant was further heated at 120° C. for 60 minutes (refer to FIG. 7D). The same operations were performed using a substrate on which CNT fragments are not fixed, and then the surface shape was observed by an atomic force microscope and it was found that the exposed portion was concaved. This suggests that a resist film without being exposed remains.

### 4. Preparation of Aqueous Dispersion Solution of CNTs

0.5 mg of single-layer CNTs was suspended in a mixed acid of 3 mL of sulfuric acid and 1 mL of nitric acid, and the resultant was subjected to an ultrasonic treatment for 2 hours. To the treated solution, water was added to make the resulting solution 8 mL, and dialyzation against 3 L of water was performed three times (molecular fractionation: 10000). To the dialyzed product, water was added to make the resulting solution as an aqueous dispersion solution of CNTs (pH: approximately 7). The concentration of the CNTs was 0.04 mg/mL.

### 5. Fixation of CNTs

The substrate in which the resist film was removed was immersed in the above aqueous dispersion solution of CNTs to bond CNTs to CNT fragments on the substrate (refer to FIG. 7E). At this time, the pH of the aqueous dispersion solution of CNTs was lowered to approximately 4 using hydrochloric acid. The resulting substrate was washed with water, and dried by spraying a nitrogen gas.

### 6. Formation of Source Electrode, Drain Electrode and Gate Electrode

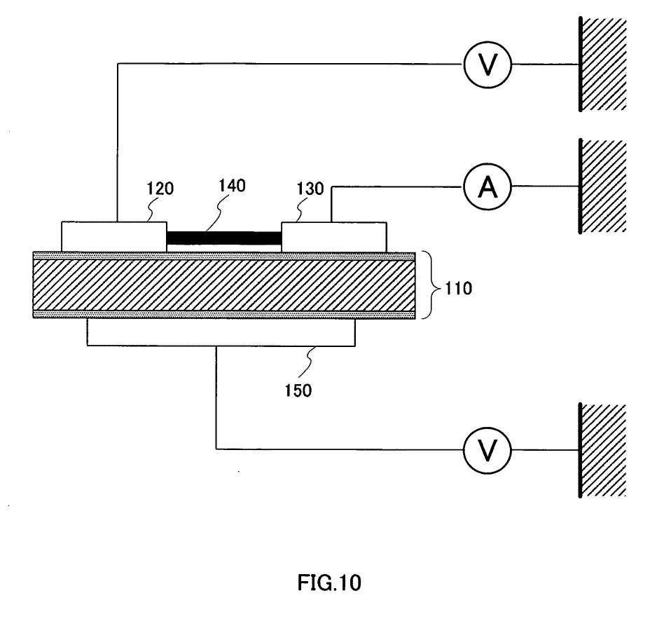

In the same procedure as in the above-mentioned “1. Pretreatment of Substrate”, a substrate surface except for a predetermined site for electrode formation (which was expanded one size larger than APS film in order to completely cover APS film by the electrode) was protected with a resist film (refer to FIG. 7F). A source electrode and a drain electrode were formed by forming a titanium thin film with a thickness of 30 nm by depositing titanium on the substrate and further forming a gold thin film with a thickness of 50 nm by depositing gold on the titanium thin film (refer to FIG. 7G). On a smooth gold electrode, a surface (the second surface) on which the source electrode and the drain electrode of the resulting substrate are not formed was placed. The gold electrode was used as a gate electrode (refer to FIG. 7H). FIG. 10 is a schematic view showing a configuration of the prepared CNT-FET. As shown in FIG. 10, source electrode 120, drain electrode 130 and channel 140 were disposed on the first surface of substrate 110, and gate electrode 150 was disposed on the second surface of substrate 110.

### 7. Results

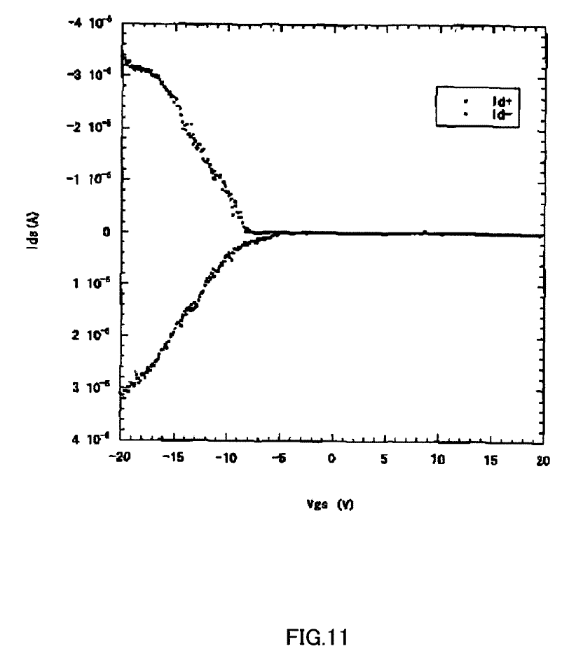

FIG. 11 is a graph showing I-Vg characteristics of the prepared CNT-FET. The horizontal axis is a gate voltage and the vertical axis is a source-drain current when a source-drain voltage is held constant (±1 V). It is understood from the graph that approximately 3×10⁻⁶ A of the source-drain current is observed in the region of −20 to −5 V of the gate voltage. In addition, it is also understood that the source-drain current is controlled by the gate voltage. Therefore, it is understood that the CNT-FET exhibits properties of FET.

### EXAMPLE 2

Example 2 shows an example of preparing a CNT-FET by bonding CNT fragments onto a substrate by electrostatic bonding.

### 1. Pretreatment of Substrate

In the same procedure as in “1. Pretreatment of Substrate” of Example 1, the pretreatment of a substrate was performed (refer to FIG. 7A and FIG. 7B).

### 2. Preparation of Aqueous Dispersion Solution of CNT Fragments

In the same procedure as in “2. Preparation of Aqueous Dispersion Solution of CNT Fragments” of Example 1, an aqueous dispersion solution of CNT fragments was prepared.

### 3. Fixation of CNT Fragments

The CNT fragments were bonded to a predetermined site for electrode formation of the pretreated substrate by adding dropwise 100 μL of the above aqueous dispersion solution of CNT fragments on the substrate at 40° C. over 15 minutes (refer to FIG. 7C). The resulting substrate was subjected to an ultrasonic treatment in dimethylformamide for approximately 30 seconds to remove the resist film, and the resultant was further heated at 120° C. for 60 minutes (refer to FIG. 7D). After performing the same operations using a substrate on which CNT fragments are not fixed, the surface shape was observed by an atomic force microscope and it was found that the exposed portion was concaved. This suggests that a resist film without being exposed remains.

### 4. Preparation of Aqueous Dispersion Solution of CNTs

In the same procedure as in “4. Preparation of Aqueous Dispersion Solution of CNTS” of Example 1, an aqueous dispersion solution of CNTs was prepared.

### 5. Fixation of CNTs

In the same procedure as in “4. Fixation of CNTS” of Example 1, CNTs were fixed to CNT fragments on the substrate (refer to FIG. 7E).

### 6. Formation of Source Electrode, Drain Electrode and Gate Electrode

In the same procedure as in “6. Formation of Source Electrode, Drain Electrode and Gate Electrode” of Example 1, individual electrodes were formed (refer to FIGS. 7E to H).

### EXAMPLE 3

Example 3 shows an example of preparing a CNT-FET by providing a mixture aqueous dispersion solution on a substrate.

### 1. Pretreatment of Substrate

In the same procedure as in “1. Pretreatment of Substrate” of Example 1, the pretreatment of a substrate was performed (refer to FIG. 8A and FIG. 8B). Thereafter, the pretreated substrate was subjected to an ultrasonic treatment in dimethylformamide for approximately 30 seconds to remove the resist film, and the resultant was further heated at 120° C. for 60 minutes (refer to FIG. 8C). The surface shape was observed by an atomic force microscope and it was found that the exposed portion was concaved. This suggests that a resist film without being exposed remains.

### 2. Preparation of Mixture Aqueous Dispersion Solution

5 mg of single-layer CNTs was suspended in a mixed acid of 3 mL of sulfuric acid and 1 mL of nitric acid, and the resultant was subjected to an ultrasonic treatment for 5 minutes. To the treated solution a hydrogen peroxide aqueous solution (500 μL) was added dropwise, and the resultant was further subjected to the ultrasonic treatment for one hour. To the treated solution, water was added to make the resulting solution 8 mL, and dialyzation against 3 L of water was performed three times (molecular fractionation: 10,000). To the dialyzed product, water was added to make the resulting solution 10 mL and the resulting solution was used as a mixture dispersion solution (pH: approximately 7) of CNTs and CNT fragments. The concentration of the mixture (CNTs and CNT fragments) was 0.5 mg/mL.

### 3. Fixation of CNT Fragments and CNTs

The mixture aqueous dispersion solution was diluted to 100-fold with distilled water. 50 μL of the diluted mixture aqueous dispersion solution was added dropwise onto the pretreated substrate, and the resultant was allowed to stand for 10 minutes to bond the CNT fragments and CNTs to the predetermined site for electrode formation of the substrate (refer to FIG. 8D). Thereafter, the substrtae was washed with water, and dried by spraying a nitrogen gas.

### 4. Formation of Source Electrode, Drain Electrode and Gate Electrode

In the same procedure as in “6. Formation of Source Electrode, Drain Electrode and Gate Electrode” of Example 1, individual electrodes were formed (refer to FIGS. 8E to G).

The present application claims the priority based on Japanese Patent Application No. 2006-100958, filed on Mar. 31, 2006, the contents of the application specification and drawings of which are hereby incorporated by reference in its entirety.

### INDUSTRIAL APPLICABILITY

A CNT-FET of the present invention may be easily produced and the production cost may be significantly reduced compared to a conventional CNT-FETbecause the channel maybe formed by a dispersion and fixation process. Needless to say, a CNT-FET of the present invention has performance at the same level or higher compared to a conventional CNT-FET, and if it is used as a pH sensor or a biosensor, detection may be performed with high sensitivity.

1. An electric field effect transistor having a source electrode and a drain electrode formed on a substrate, a channel composed of one or more carbon nanotubes connecting the source electrode and the drain electrode, and carbon nanotube fragments fixing the carbon nanotubes on the substrate; wherein
the carbon nanotube fragments each have a carboxyl group or a derivative of a carboxyl group on the surface, have a length of 1.5 μm or less, and are selectively bonded to a site for forming a source electrode and a site for forming a drain electrode of the substrate.

2. The electric field effect transistor according to claim 1, wherein the carbon nanotube fragments are obtained by subjecting carbon nanotubes dispersed in acid to a hydrogen peroxide treatment.

3. The electric field effect transistor according to claim 2, wherein the acid is a mixed acid of sulfuric acid and nitric acid.

4. (canceled)

5. The electric field effect transistor according to claim 1, wherein the carbon nanotube fragments are bonded by covalent bonding to the site for forming a source electrode and the site for forming a drain electrode of the substrate.

6. The electric field effect transistor according to claim 5, wherein the carbon nanotube fragments are bonded by amide bonding to the site for forming a source electrode and the site for forming a drain electrode of the substrate.

7. The electric field effect transistor according to claim 1, wherein the carbon nanotube fragments ate electrostatically bonded to the site for forming a source electrode and the site for forming a drain electrode of the substrate.

8. (canceled)

9. A method for producing an electric field effect transistor having a source electrode and a drain electrode formed on a substrate and a channel composed of one or more carbon nanotubes connecting the source electrode and the drain electrode, comprising:
a step of providing an aqueous dispersion solution of carbon nanotube fragments each having a carboxyl group or a derivative of a carboxyl group on the surface and having a length of 1.5 μm or less to a predetermined site for forming a source electrode and a predetermined site for forming a drain electrode of the substrate to selectively bond the carbon nanotube fragments to the predetermined sites of the substrate;
a step of providing carbon nanotubes to the predetermined sites of the substrate to bond the carbon nanotubes to the carbon nanotube fragments bonded to the substrate; and
a step of forming a source electrode at the predetermined site for forming a source electrode of the substrate and forming a drain electrode at the predetermined site for forming a drain electrode of the substrate.

10. A method for producing an electric field effect transistor having a source electrode and a drain electrode formed on a substrate and a channel composed of one or more carbon nanotubes connecting the source electrode and the drain electrode, comprising:
a step of providing an aqueous dispersion solution of a mixture of carbon nanotube fragments each having a carboxyl group or a derivative of a carboxyl group on the surface and having a length of 1.5 μm or less and carbon nanotubes to a predetermined site for forming a source electrode and a predetermined site forming a drain electrode of the substrate to selectively bond the carbon nanotube fragments to the predetermined sites of the substrate and to bond the carbon nanotubes to the carbon nanotube fragments bonded to the substrate; and
a step of forming a source electrode at the predetermined site for forming a source electrode of the substrate and forming a drain electrode at the predetermined site for forming a drain electrode of the substrate.

11. The electric field effect transistor according to claim 1, wherein the interval between the source electrode and the drain electrode is 2 to 10 μm.
